(19) United States
(12) Patent Application Publication
(10) Pub. No.: US 2016/0163979 A1
(43) Pub. Date: Jun. 9, 2016

(54) RESISTIVE MEMORY DEVICES

(71) Applicant: SAMSUNG ELECTRONICS CO., LTD., SUWON-SI (KR)

(72) Inventors: SEUNG-RYUL LEE, ASAN-SI (KR); IN-GYU BAEK, CHEONAN-SI (KR); SAIFUL-HAQUE MISHA, ASAN-SI (KR); HYUN-SANG HWANG, CHEONAN-SI (KR)

(73) Assignee: POSTECH ACADEMY-INDUSTRY FOUNDATION, POHANG-SI (KR)

(21) Appl. No.: 14/955,096

(22) Filed: Dec. 1, 2015

(30) Foreign Application Priority Data
Dec. 3, 2014 (KR) 10-2014-0172457

(51) Int. Cl. H01L 45/00; H01L 27/24

(52) U.S. Cl. CPC H01L 45/1266; H01L 45/085; H01L 45/1233; H01L 45/146; H01L 27/2463

(57) ABSTRACT

A resistive memory device includes: a first electrode; a variable resistive material layer that is formed on the first electrode and includes a metal oxide NₓMO_{y} (wherein 0.001<x<0.30 and 0.5<y<2.5) doped with nitrogen; and a second electrode that is formed on the variable resistive material layer. The variable resistive material layer has a multibit memory characteristic.

### CROSS-REFERENCE TO RELATED APPLICATION

This application claims the benefit of Korean Patent Application No. 10-2014-0172457, filed on Dec. 3, 2014, in the Korean Intellectual Property Office, the disclosure of which is incorporated herein in its entirety by reference.

### BACKGROUND

Example embodiments of the inventive concepts relate to a resistive memory device. For example, at least some example embodiments relate to a resistive memory device including a variable resistive material layer.

Resistive memory devices may utilize a variable resistive material whose resistance varies at a particular voltage. For example, if a set voltage is applied to the variable resistive material, an on state may occur to lower the resistance of the variable resistive material. Likewise, if a reset voltage is applied to the variable resistive material, an off state may occur to increase the resistance of the variable resistive material. Conventionally, after repeated operations of the on and off states, an electrical path that is formed by motions of vacancies of the variable resistive material may not be uniformly controlled. Therefore, the resistive memory devices may have poor reliability.

### SUMMARY

Example embodiments of inventive concepts provide a resistive memory device having an improved reliability and/or able to perform a multibit storage operation.

According to some example embodiments of the inventive concepts, a resistive memory device may include a first electrode; a variable resistive material layer formed on the first electrode, the variable resistive material layer including a metal oxide doped with nitrogen NₓMO_{y} (wherein 0.001<x<0.30 and 0.5<y<2.5), the variable resistive material layer configured to exhibit a multibit memory characteristic; and a second electrode formed on the variable resistive material layer.

In some example embodiments, the metal oxide doped with nitrogen includes one or more of a tantalum oxide doped with nitrogen, a tungsten oxide doped with nitrogen, a manganese oxide doped with nitrogen, a cobalt oxide doped with nitrogen, a titanium oxide doped with nitrogen, a hafnium oxide doped with nitrogen, and an iron oxide doped with nitrogen.

In some example embodiments, the metal oxide doped with nitrogen includes a tantalum oxide NₓTaO_{y} , and 0.02<x<0.15.

In some example embodiments, the variable resistive material layer exhibits a bipolar memory characteristic.

In some example embodiments, a current flowing through the variable resistive material layer is a set current when a set voltage is applied thereto, a current flowing through the variable resistive material is a half set current when half of the set voltage is applied thereto, and a ratio of the set current to the half set current is between 2 and 3.5 when the resistive memory device is operating in a low resistance state such that the resistive memory device exhibits non-linearity in the low resistance state.

In some example embodiments, the non-linearity exhibited by the variable resistive material layer is between 2 and 2.5.

In some example embodiments, the resistive memory device further includes a conduction assisting layer between the variable resistive material layer and one or more of the first electrode and the second electrode.

In some example embodiments, the conduction assisting layer includes one or more of tantalum, hafnium, zirconium, aluminum, titanium, and nickel.

In some example embodiments, the conduction assisting layer is configured to one of supply oxygen to the variable resistive material layer or remove oxygen vacancies therefrom.

In other example embodiments, the resistive memory device may include a plurality of first electrodes in parallel with one another; a plurality of second electrodes crossing the plurality of first electrodes, the plurality of second electrodes in parallel with one another; and a plurality of memory cells at cross points between the plurality of first electrodes and the plurality of second electrodes, each of the plurality of memory cells respectively including a variable resistive material layer that exhibits a multibit memory characteristic.

In some example embodiments, the variable resistive material layer includes a metal oxide doped with nitrogen NₓMO_{y} (wherein 0.001<x<0.30 and 0.5<y<2.5).

In some example embodiments, the metal oxide doped with nitrogen includes a tantalum oxide doped with nitrogen NₓTaO_{y} (wherein 0.02<x<0.15).

In some example embodiments, the plurality of memory cells may further include a plurality of switching elements between the variable resistive material layers and the plurality of second electrodes.

In some example embodiments, the plurality of memory cells may further include conduction assisting layers between the variable resistive material layers and the plurality of first electrodes.

In some example embodiments, a current flowing through the variable resistive material layer is a set current when a set voltage is applied thereto, a current flowing through the variable resistive material is a half set current when half of the set voltage is applied thereto, and a ratio of the set current to the half set current is between 2 and 3.5 when operating the resistive memory device is in a low resistance state such that the resistive memory device exhibits non-linearity in the low resistance state.

In other example embodiments, the resistive memory device may include a substrate having a first electrode thereon; a variable resistive material layer on the first electrode, the variable resistive material layer including a metal oxide doped with nitrogen; and a second electrode on the variable resistive material layer.

In some example embodiments, an atomic percentage of nitrogen in the metal oxide doped with nitrogen may be between 0.1 atomic percent and 30 atomic percent.

In some example embodiments, the metal oxide doped with nitrogen may include tantalum oxide, and the atomic percentage of the nitrogen in the tantalum oxide is between 0.2 atomic percent and 15 atomic percent.

In some example embodiments, a current flowing through the variable resistive material layer may be a set current when a set voltage is applied thereto, a current flowing through the variable resistive material is a half set current when half of the set voltage is applied thereto, and a ratio of the set current to the half set current is between 2 and 3.5 when the resistive memory device is operating in a low resistance state.

In some example embodiments, the resistive memory device may exhibit a plurality of discrete resistance states when respective compliance currents are applied thereto are such that the resistive memory device is configured to store 3 bits of information, and the compliance currents are between 10 μA and 120 μA.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view illustrating a resistive memory device according to some example embodiments;

FIGS. 2A and 2B are schematic views illustrating a conduction mechanism of a resistive memory device according to some example embodiments;

FIG. 3 is a graph illustrating an operation of a resistive memory device according to some example embodiments;

FIG. 4 is a graph illustrating an operation of a resistive memory device according to other example embodiments;

FIG. 5 is a cross-sectional view illustrating a resistive memory device according to other example embodiments;

FIG. 6 is a cross-sectional view illustrating a resistive memory device according to other example embodiments;

FIG. 7 is a cross-sectional view illustrating a resistive memory device according to other example embodiments;

FIG. 8 is a cross-sectional view illustrating a resistive memory device according to other example embodiments;

FIGS. 9A through 16B are graphs illustrating electrical characteristics of resistive memory devices according to some example embodiments;

FIG. 17 is a block diagram illustrating a memory device using a resistive memory device according to some example embodiments;

FIG. 18 is a block diagram illustrating a memory card system using a resistive memory device according to some example embodiments;

FIG. 19 is a block diagram illustrating a resistive memory module using a resistive memory device according to some example embodiments; and

FIG. 20 is a block diagram illustrating a computing system using a resistive memory device according to some example embodiments.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

Example embodiments of the inventive concepts will now be described more fully with reference to the accompanying drawings, in which some example embodiments of the inventive concepts are shown. The inventive concepts may, however, be embodied in many different forms and should not be construed as being limited to the example embodiments set forth herein; rather, these embodiments are provided so that this disclosure will be thorough and complete, and will fully convey example embodiments of the inventive concepts. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which exemplary embodiments belong.

Hereinafter, some example embodiments of the inventive concepts will be described in detail with reference to the attached drawings.

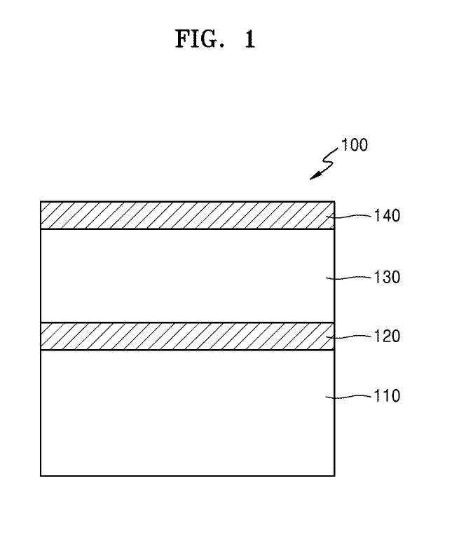

FIG. 1 is a cross-sectional view illustrating a resistive memory device 100 according to some example embodiments.

Referring to FIG. 1, the resistive memory device 100 may include a first electrode 120, a variable resistive material layer 130, and a second electrode 140 that are sequentially formed on a substrate 110.

The substrate 110 may include a silicon substrate, a germanium substrate, a silicon-germanium substrate, a silicon-on-insulation (SOI) substrate, or the like. Although not shown in FIG. 1, a conductive area (not shown) that is doped with dopant may be formed on the substrate 100. Also, a switching element (not shown), such as a diode, a transistor, or the like that applies power and/or a signal to the resistive memory device 100, may be further formed on the substrate 100. Line structures (not shown), which electrically connect the resistive memory device 100 to the switching element or electrically connect the switching element to the conductive area of the substrate 110, may be further formed on the substrate 110. An insulating layer (not shown) may be further formed on the substrate 110 to cover the line structures and the switching element.

The variable resistive material layer 130 may include a material that shows a resistance characteristic varying according to a voltage applied to the variable resistive material layer 130. According to at least some example embodiments, the variable resistive material layer 130 may include a metal oxide including nitrogen. For example, the metal oxide may include at least one of tantalum oxide, titanium oxide, iron oxide, tungsten oxide, manganese oxide, and cobalt oxide. According to some example embodiments, the variable resistive material layer 130 may include a tantalum oxide including nitrogen. For example, the variable resistive material layer 130 may include NxTaOy (wherein 0.001<x<0.30). The variable resistive material layer 130 may include a nitrogen-tantalum oxide having a nitrogen content between about 2 percent-by-weight (2 wt %) and about 15 percent-by-weight (15 wt %). According to some example embodiments, the variable resistive material layer 130 may have a thickness equal to or lower than about 10 nm, but the thickness of the variable resistive material layer 130 is not limited thereto.

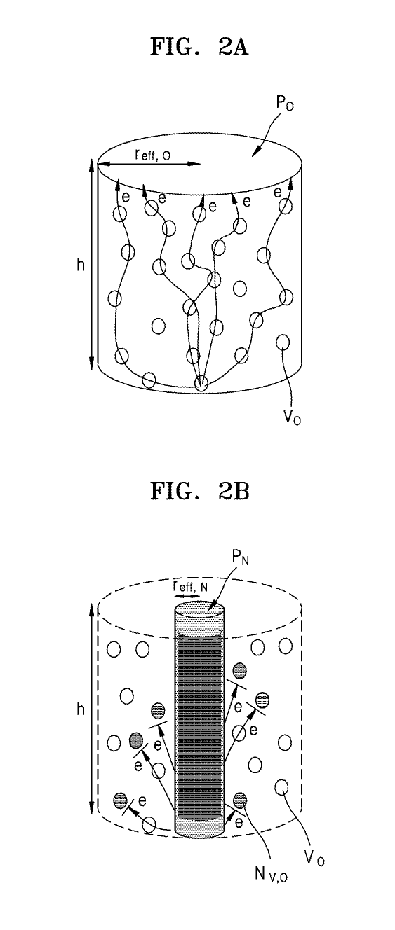

FIGS. 2A and 2B schematically illustrate a conduction mechanism that may occur in the variable resistive material layer 130 of FIG. 1 including a metal oxide layer including nitrogen. FIG. 2A schematically illustrates paths, through which electrons e migrate in a conventional metal oxide layer that does not include nitrogen, with arrows for comparative purposes. FIG. 2B schematically illustrates paths, through which electrons e migrate in a metal oxide layer including nitrogen according to example embodiments, with arrows.

Referring to FIG. 2A, oxygen vacancies VO may be arranged at a preset concentration in a conventional metal oxide layer that does not include nitrogen. A current may flow in the metal oxide layer due to the migrations of the electrons e through the oxygen vacancies VO. Since oxygen vacancies VO present within a first effective radius reff,O may participate in the migrations of the electrons e, a conductive path (PO) having the first effective radius reff,O may be formed.

Referring to FIG. 2B, according to some example embodiments, nitrogen atoms NV,O may be positioned in some of the oxygen vacancies VO in the metal oxide layer that includes the nitrogen atoms NV,O at a desired (or, alternatively, a preset) concentration. Due to interactions with the nitrogen atoms NV,O existing in positions of the oxygen vacancies VO, the activation energy required to migrate the electrons e through the positions of the oxygen vacancies VO may increase. Therefore, a probability of the migration of the electrons e through the nitrogen atoms NV,O may decrease. In other words, migration paths of the electrons e may be confined to the positions of the oxygen vacancies VO present within a shorter distance, due to the nitrogen atoms NV,O that are adjacent to one another. Therefore, in at least some example embodiments, the metal oxide layer 130 such that a conductive path PN therein has a second effective radius reff,N shorter than the first effective radius reff,O.

According to a result acquired from Equation 1 below, if the number of oxygen vacancies related to a conductive path as described above is nV, and a concentration of oxygen vacancies in a variable resistive material layer is Cv, the concentration Cv of the oxygen vacancies in the variable resistive material layer may increase with a decrease in an effective radius reff of the conductive path and may increase with an increase in the number nv of oxygen vacancies. If the variable resistive material layer has similar resistances, the number nv of oxygen vacancies for forming an effective conductive path may be the same. Therefore, the concentration Cv of the oxygen vacancies may increase with a decrease in the effective radius reff, and thus a locally strong conductive path may be formed.

$${C}_{V} = \frac{{n}_{V}}{{π ( {r}_{eff} )}^{2} h} \qquad ( 1 )$$

If the effective radius reff of the conductive path is relatively large, a plurality of paths, through which electrons may flow, may exist in the conductive path. Each time a programming voltage or an erasing voltage is applied to the variable resistive material layer, electrons may flow through other paths. Therefore, when programing or erasing is repeated, a conventional variable resistive material layer may exhibit non-uniform operation characteristics such as a non-uniform voltage, a non-uniform resistance distribution, etc. In particular, non-uniformities of a voltage and a resistance may be intensified at a low operation current. Also, when performing the programming or the erasing, oxygen ions or oxygen vacancies may migrate to form a conductive path and may migrate to remove the conductive path. If an effective radius of the conductive path is relatively large, a reliability of a resistive memory device may be deteriorated by the migrations of the oxygen ions or the oxygen vacancies.

According to at least some example embodiments, the variable resistive material layer 130 may include a metal oxide layer including nitrogen and include a conductive path PN having the second effective radius reff,N as shown in FIG. 2B. Therefore, the resistive memory device 100 including the variable resistive material layer 130 may show a uniform operation characteristic, such as a uniform voltage, a uniform resistance distribution, or the like, and have a high reliability at a low operation current.

According to some example embodiments, the variable resistive material layer 130 may include NxTaOy (wherein 0.001<x<0.30). In other words, the variable resistive material layer 130 may have a nitrogen content between about 0.1 atomic percentage (at %) and about 30 at %. When the nitrogen content included in the variable resistive material layer 130 is higher than or equal to about 30 at %, nitrogen may be positioned in many of oxygen vacancies existing in the metal oxide layer which may make it difficult for the electronics to migrate. Therefore, the variable resistive material layer 130 may have increased resistance, and thus, the resistive memory device 100 may have poor electrical characteristics. When the nitrogen content included in the variable resistive material layer 130 is lower than or equal to about 0.1 at %, the number of nitrogen atoms positioned in oxygen vacancies in the metal oxide layer may be small. Therefore, it may be difficult to effectively decrease an effective radius of a conductive path. In contrast, in at least some example embodiments, the variable resistive material layer 130 may include nitrogen between about 0.1 at % and about 30 at %, and thus the resistive memory device 100 may have a uniform voltage and/or a uniform resistance distribution and a high reliability in a programming operation or an erasing operation (in a set operation or in a reset operation) even at a low operation current.

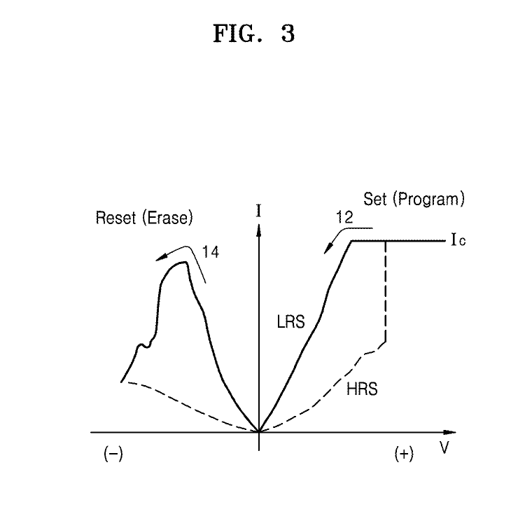

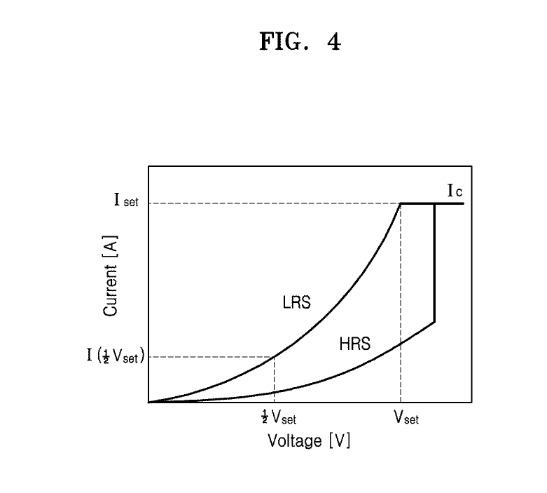

The variable resistive material layer 130 may include a material having a bipolar memory characteristic. An operation method using the bipolar memory characteristic of the variable resistive material layer 130 is schematically illustrated in FIG. 3.

Referring to FIG. 3, the variable resistive material layer 130 may include a material whose resistance is changed from a high resistance state HRS into a low resistance state LRS. Particularly, when a voltage is applied from a positive bias area, a current may increase at a desired (or, alternatively, a preset) slope and then may rapidly increase at a particular threshold voltage (or a set threshold voltage). Here, a transition from the high resistance state HRS to the low resistance state LRS may occur in the variable resistive material layer 130, and this operation may be referred to as a set operation or a programming operation. When the current rapidly increases at the set threshold voltage, a current value may be limited by using a compliance current IC. When a voltage is applied with the compliance current Ic and decreases to a particular threshold voltage (or a reset threshold voltage) of a negative bias area, the low resistance state LRS of the variable resistive material layer 130 may be maintained. The current may rapidly decrease at the reset threshold voltage, and thus a transition from the low resistance state LRS into the high resistance state HRS may occur. This operation may be referred to as a reset operation or an erasing operation.

For convenience of description, a set operation 12 is defined as occurring when the current starts decreasing from the compliance current Ic in the positive bias area. Also, a voltage of a point at which the current starts decreasing from the compliance current Ic in the positive bias area is defined as a set voltage Vset. A set resistance Rset is defined as the set voltage Vset divided by the compliance current Ic in the low resistance state LRS. A reset operation 14 is defined as occurring when the current that has been increasing in the low resistance state LRS starts decreasing in the negative bias area. A voltage of a point at which the current starts decreasing in the negative bias area is defined as a reset voltage Vreset, and a current at this time is defined as a reset current Ireset. A reset resistance Rreset is defined as the reset voltage Vreset divided by the reset current Ireset.

According to example embodiments, the variable resistive material layer 130 may have a uniform operation characteristic at a low operation current to enable a multilevel storage. For example, the variable resistive material layer 130 may change the compliance current Ic to be used so as to store information of 2 bits or information of 3 bits. In other words, the variable resistive material layer 130 may show 4 different resistance states or 8 different resistance states when changing the compliance current Ic. For example, 8 compliance currents Ic may be used to store information of 3 bits. Therefore, a size of the compliance current Ic may decrease to secure several sections of the compliance current Ic at an appropriate current value or less. In particular, the size of the compliance current Ic may decrease with an increase in the number of bits stored in the variable resistive material layer 130, and thus a uniform characteristic may be required at a low operation current. The variable resistive material layer 130 according to at least some example embodiments may have a uniform operation characteristic at a low operation current (e.g., the resistive material layer 130 may have relatively high sensing margin even at a low operation current). Therefore, the magnitude of the compliance current Ic required may decrease, and thus a multilevel storage mode may be realized.

According to at least some example embodiments, the variable resistive material layer 130 may exhibit a non-linearity NL at a low resistance state to enable a multilevel storage. A definition of the non-linearity NL may be described with reference to a voltage-current graph of a resistive memory device shown in FIG. 4.

FIG. 4 is a graph illustrating an operation of a resistive memory device according to example embodiments.

Referring to FIG. 4, a set current Iset may indicate a current value of a set voltage Vset in a low resistance state LRS. A voltage that is 1/2 of the set voltage Vset may be referred to as a half set voltage 1/2Vset, and a current value at the half set voltage 1/2Vset may be referred to as a half set current I(1/2Vset). As checked with Equation 2 below, the non-linearity NL may be defined as a ratio of the set current Iset to the half set current I(1/2Vset).

$$NL = \frac{{I}_{set}}{I ( 1 / 2 {V}_{set} )} \qquad ( 2 )$$

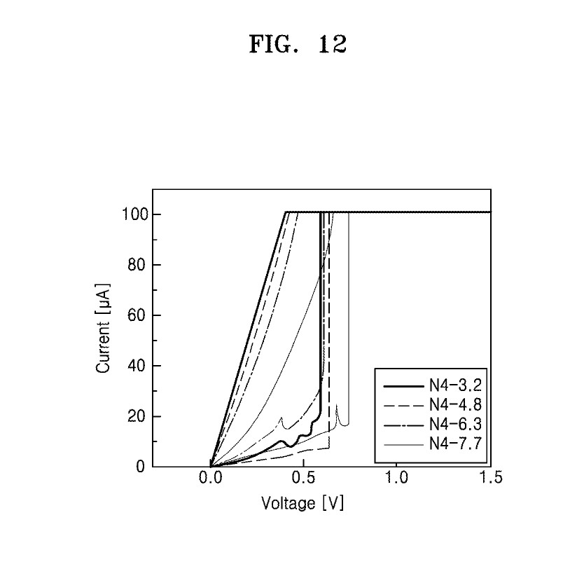

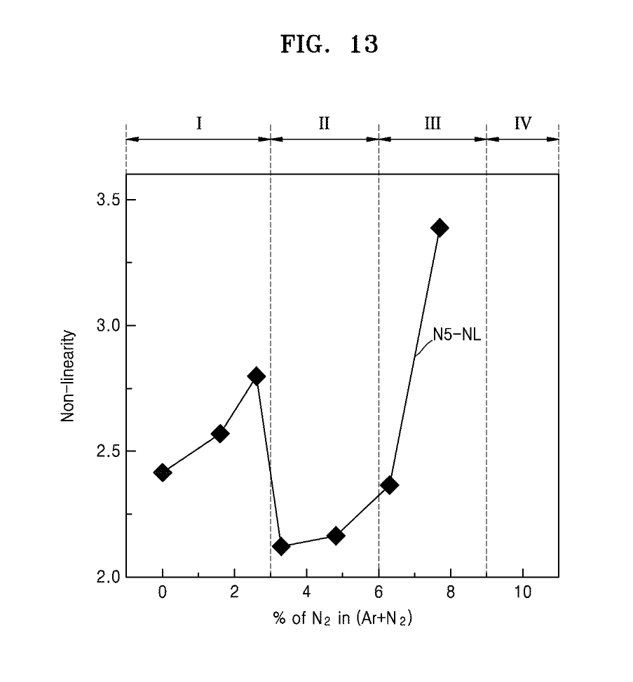

According to some example embodiments, the variable resistive material layer 130 may have a non-linearity NL between about 2 and about 3.5. In this case, the resistive memory device 100 may store information of 2 bits. In other example embodiments, the variable resistive material layer 130 may have a non-linearity NL between about 2 and about 2.5. In this case, the resistive memory device 100 may store information of 3 bits. As the current-voltage curve of the variable resistive material layer 130 is almost linear (i.e., has a low non-linearity NL value), interference may be reduced (or, alternatively eliminated) between the voltage-current curves in different levels of compliance currents Ic of a multibit storage mode, and a sensing margin between different levels may increase. Therefore, the resistive memory device 100 including the variable resistive material layer 130 according to example embodiments may realize a relatively reliable multilevel storage mode. Multilevel storage characteristics related to a non-linearity NL will be described in detail later with reference to FIGS. 12 through 15.

According to some example embodiments, the non-linearity NL of the variable resistive material layer 130 may vary according to a nitrogen content. For example, a tantalum oxide that is doped with nitrogen between about 0.1 at % and about 30 at % may have a non-linearity NL between about 2 and about 3.5. Therefore, the resistive memory device 100 may store information of 2 bits when the variable resistive material layer 130 includes the tantalum oxide that is doped with nitrogen between about 0.1 at % and about 30 at %. Further, within the aforementioned range, a tantalum oxide that is doped with nitrogen between about 2 at % and about 15 at % may have a non-linearity NL between about 2 and about 2.5. Therefore, the resistive memory device 100 may store information of 3 bits when the variable resistive material layer 130 includes the tantalum oxide that is doped with nitrogen between about 2 at % and 15 at %.

The resistive memory device 100 according to example embodiments may have a sufficiently high sensing margin according to changes in a compliance current Ic caused by a high linearity of the variable resistive material layer 130 (i.e., a low NL value). Therefore, a multilevel storage mode of 2 bits or more, for example, of 3 bits may be stably realized. The resistive memory device 100 may have an improved density of integration.

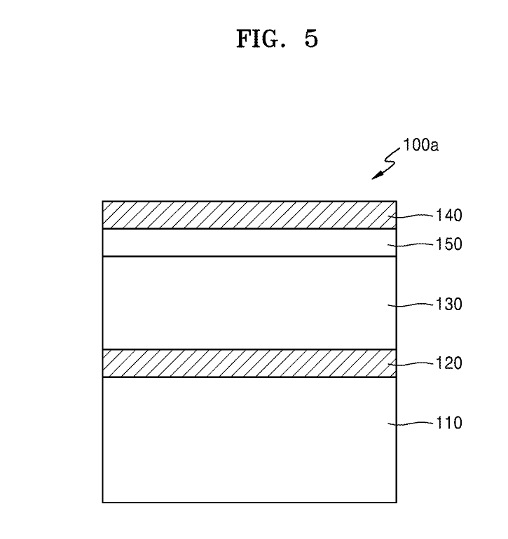

FIG. 5 is a cross-sectional view illustrating a resistive memory device 100a according to some example embodiment.

Referring to FIG. 5, the resistive memory device 100a is similar to the resistive memory device 100 described with reference to FIG. 1, except that the resistive memory device 100a further includes a first conduction assisting layer 150. Therefore, differences between the resistive memory device 100a and the resistive memory device 100 will be mainly described.

The first conduction assisting layer 150 is between the variable resistive material layer 130 and the second electrode 140. When a programming or erasing operation is performed with respect to the variable resistive material layer 130, the first conduction assisting layer 150 may operate as an oxygen supply layer that supplies oxygen to the variable resistive material layer 130 or as an oxygen vacancy scavenging layer that removes oxygen vacancies. According to some example embodiments, the first conduction assisting layer 150 may include a reactive metal having a high reactivity with respect to a metal oxide. For example, the first conduction assisting layer 150 may include tantalum, hafnium, zirconium, tungsten, aluminum, titanium, and/or nickel. According to some example embodiments, the first conduction assisting layer 150 may have a thickness lower than or equal to about 10 nm, but the thickness of the first conduction assisting layer 150 is not limited thereto.

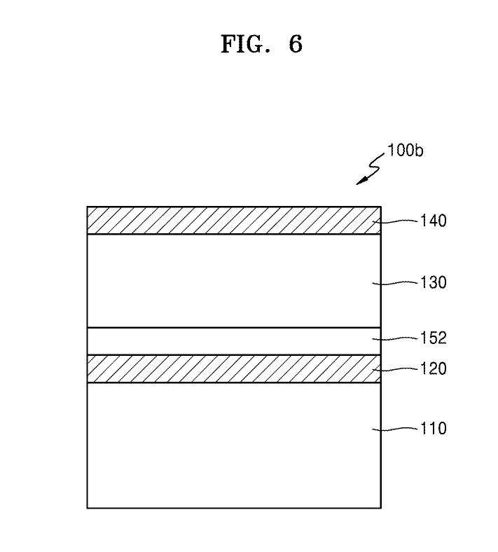

FIG. 6 is a cross-sectional view illustrating a resistive memory device 100b according to some example embodiments.

Referring to FIG. 6, the resistive memory device 100b is similar to the resistive memory device 100 described with reference to FIG. 1, except that the resistive memory device 100b further includes a second conduction assisting layer 152 between the variable resistive material layer 130 and the first electrode 120.

The second conduction assisting layer 152 may be between the variable resistive material layer 130 and the first electrode 120. When a programming or erasing work is performed with respect to the variable resistive material layer 130, the second conduction assisting layer 152 may operate as an oxygen supply layer that supplies oxygen to the variable resistive material layer 130 or as an oxygen vacancy scavenging layer that erases oxygen vacancies. According to some example embodiments, the second conduction assisting layer 152 may include a reactive metal having a high reactivity with respect to a metal oxide. For example, the second conduction assisting layer 152 may include tantalum, hafnium, zirconium, tungsten, aluminum, titanium, and/or nickel. According to some example embodiments, the second conduction assisting layer 152 may have a thickness lower than or equal to about 10 nm, but the thickness of the second conduction assisting layer 152 is not limited thereto.

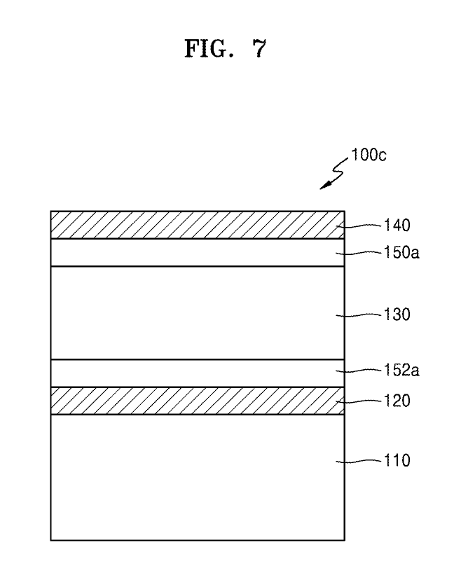

FIG. 7 is a cross-sectional view illustrating a resistive memory device 100c according to some example embodiments.

Referring to FIG. 7, the resistive memory device 100c is similar to the resistive memory device 100 described with reference to FIG. 1, except that the resistive memory device 100c further includes first and second conduction assisting layers 150a and 152a.

The first conduction assisting layer 150a may be between the variable resistive material layer 130 and the second electrode 140, and the second conduction assisting layer 152a may be between the variable resistive material layer 130 and the first electrode 120. The first and second conduction assisting layers 150a and 152a may include the same type of material or different types of materials. Each of the first and second conduction assisting layers 150a and 152a may have a thickness higher than or equal to 10 nm, but the thicknesses of the first and second conduction assisting layers 150a and 152 are not limited thereto.

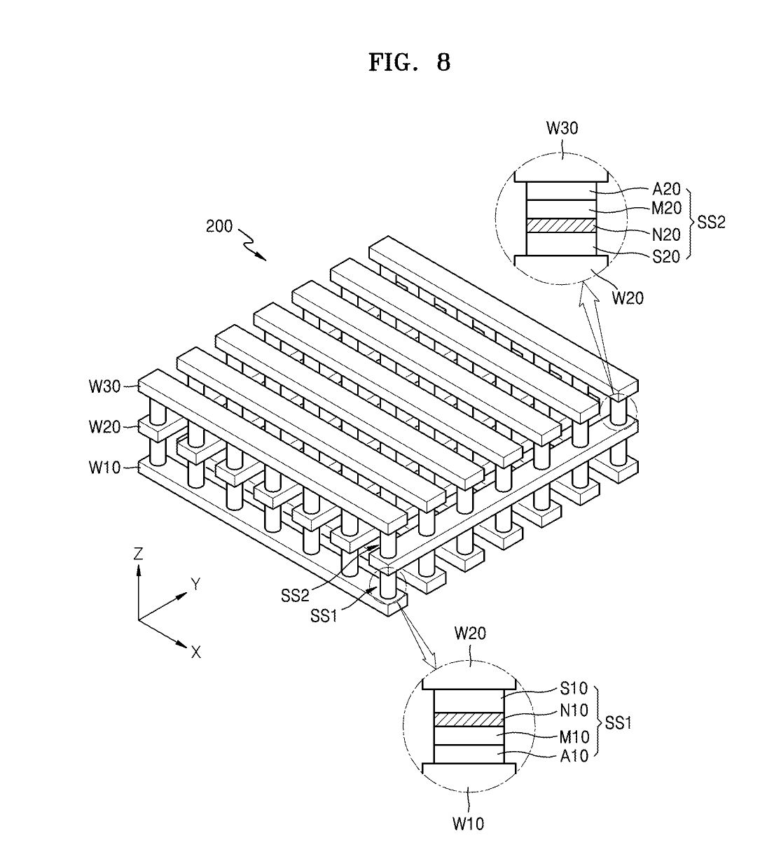

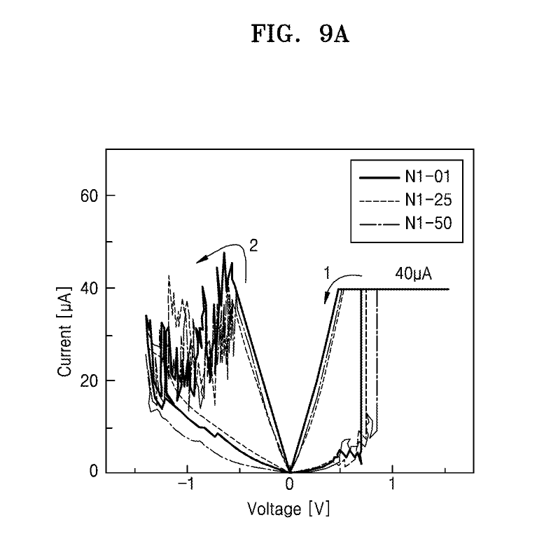

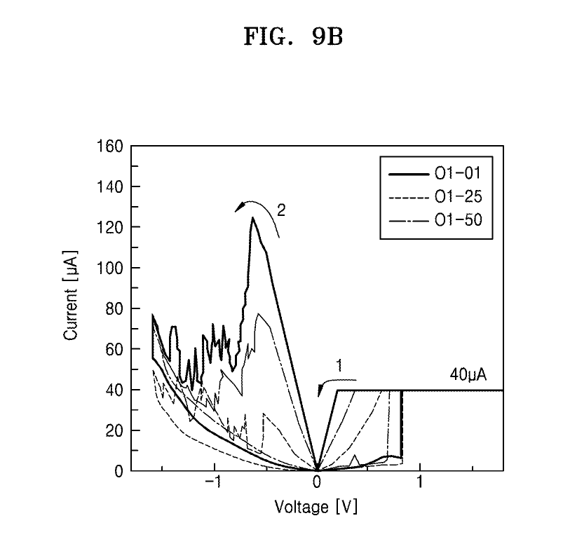

FIG. 8 is a perspective view illustrating a resistive memory device 100d according to some example embodiments. The resistive memory device 100d is a cross-point type resistive memory device.

Referring to FIG. 8, a plurality of first electrodes W10 may be formed to extend so as to be parallel with one another in a first direction, e.g., in an X direction. A plurality of second electrodes W20 may be formed to extend so as to be parallel with one another in a second direction crossing the plurality of first electrodes W10, e.g., in an Y direction. First stack structures (or first memory cells) SS1 may be formed at cross points between the first electrodes W10 and the second electrodes W20.

The first stack structures SS1 may include first conduction assisting layers A10, first memory layers M10, first intermediate electrodes N10, and first switching elements S10 that are sequentially stacked on the first electrodes W10. The first memory layers M10 may include variable resistive material layers as described with reference to FIG. 1. The first switching elements S10 may be two-way diodes, threshold switching devices, or varistors but are not limited thereto. The first electrodes W10 and the first intermediate electrodes N10 may respectively correspond to the first and second electrodes 120 and 140 of FIG. 1. In some example embodiments, the second electrodes W20 may be formed of the same type of material as that of which the first electrodes W10 are formed. In other example embodiments, the second electrodes W20 may be formed of a different type of material from that of which the first electrodes W10 are formed.

Third electrodes W30 may be formed to keep desired (or, alternatively, preset) distances from upper surfaces of the second electrodes W20. The third electrodes W30 may cross the second electrodes W20 and may be arranged at equal intervals. Second stack structures (or second memory cells) SS2 may be arranged at cross points between the second electrodes W20 and the third electrodes W30. While FIG. 8 illustrates a scenario in which the second stack structures SS2 have upside-down structures (i.e., reverse structures) of the first stack structures SS1, in other example embodiments, the second stack structures SS2 may have the same stack structures as the first stack structures SS1. In more detail, the second stack structures SS2 may include second switching elements S20, second intermediate electrodes N20, second memory layers M20, and second conduction assisting layers A20.

Experimental Examples of a resistive memory device according to example embodiments will now be described.

Resistive memory devices according to some example embodiments may be manufactured according to methods that will be described below.

In operation 910, a silicon oxide layer may be formed on a silicon substrate. In operation 920, a titanium layer serving as an adhesion layer may be formed on the silicon oxide layer. In operation 930, a first electrode may be formed on the titanium layer using platinum by a plasma enhanced chemical vapor deposition (PECVD) process. In operation, 940, an insulating layer may be formed on the first electrode using silicon oxide by a PECVD process and then patterned to form a via hole having a diameter of about 250 nm.

In operation 950, a variable resistive material layer may be formed in the via hole in an atmosphere of a mixture gas of nitrogen and argon by radio frequency (RF) magnetron sputtering using a tantalum oxide (Ta2O5) target. The variable resistive material layer may be a tantalum oxide layer including nitrogen having a preset concentration.

In operation 960, a second electrode may be formed on the variable resistive material layer using tantalum by a direct current (DC) sputtering method to manufacturer the resistive memory device according to some example embodiments.

As represented in Table 1 below, variable resistive material layers according to Experimental Examples are manufactured with changing a concentration of nitrogen in the mixture gas. For example, variable resistive material layers according to first through seventh Experimental Examples are formed in an atmosphere of a mixture gas having a nitrogen ratio between about 1.6% and about 9.0% in the mixture gas. As a Comparative Example, a variable resistive material layer including a tantalum oxide is formed in an atmosphere of an argon gas without including a nitrogen gas.

TABLE 1

| | Nitrogen Content | |
|---|---|---|
| | [%] in Mixture Gas of | Nitrogen Content |
| | Argon and Nitrogen | [at %] in NₓTaO_{y} |
| Experimental Example 1 | 1.6 | 0.1 |
| Experimental Example 2 | 2.6 | — |
| Experimental Example 3 | 3.2 | 2.0 |
| Experimental Example 4 | 4.8 | — |
| Experimental Example 5 | 6.3 | 15.0 |
| Experimental Example 6 | 7.7 | — |
| Experimental Example 7 | 9.0 | 30.0 |
| Comparative Example | 0.0 | — |

Contents or compositions of nitrogen included in the variable resistive material layers manufactured according to Experimental Examples 1, 3, 5 and 7 are measured. For example, the variable resistive material layer of Experimental Example 1 that is formed in an atmosphere of a nitrogen gas of about 1.6% is a tantalum oxide including nitrogen of about 0.1 at %. Also, the variable resistive material layer of Experimental Example 3 that is formed in an atmosphere of a nitrogen gas of about 3.2% is a tantalum oxide including nitrogen of about 2.0 at %. The variable resistive material layer of Experimental Example 5 that is formed in an atmosphere of a nitrogen gas of about 6.3% is a tantalum oxide including nitrogen of about 15.0 at %. The variable resistive material layer of Experimental Example 7 that is formed in an atmosphere of a nitrogen gas of about 9.0% is a tantalum oxide including nitrogen of about 30.0 at %.

An electrical characteristic and a reliability of a resistive memory device including a metal oxide layer including nitrogen according to Experimental Examples will now be described in comparison with Comparative Example with reference to FIGS. 9A through 11.

FIGS. 9A and 9B are graphs illustrating an operation characteristic of a resistive memory device according to example embodiments. FIG. 9A illustrates an operation characteristic of the resistive memory device according to Experimental Example 3. FIG. 9B illustrates an operation characteristic of the resistive memory device according to Comparative Example.

Referring to FIGS. 9A and 9B, in FIGS. 9a and 9B, one cycle may include a set operation (or a programming operation) and a reset operation (or an erasing operation). In other words, arrows 1 of FIGS. 9A and 9B show a set operation in which a transition from a high resistance state into a low resistance state occurs when a set voltage that is a positive bias is applied to the resistive memory device. Arrows 2 of FIGS. 9A and 9B show a reset operation in which a transition from the low resistance state into the high resistance state occurs when a reset voltage that is a negative bias is applied to the resistive memory device.

As illustrated in FIG. 9A, all of a first cycle N1-01, a 25th cycle N1-25, and a 50th cycle N1-50 of the resistive memory device according to Experimental Example 3 have similar set voltages or similar reset voltages. In particular, the resistive memory device has a uniform operation characteristic (including relatively linear current-voltage curves in low resistance states) at a low compliance current Ic of 40 μA.

As illustrated in FIG. 9B, a first cycle O1-01, a 25th cycle O1-25, and a 50th cycle (O1-50) of the resistive memory device according to Comparative Example have set voltages, reset voltages, or reset currents that vary based on the number of cycles relatively more than the resistive memory device according to Experimental Example 3.

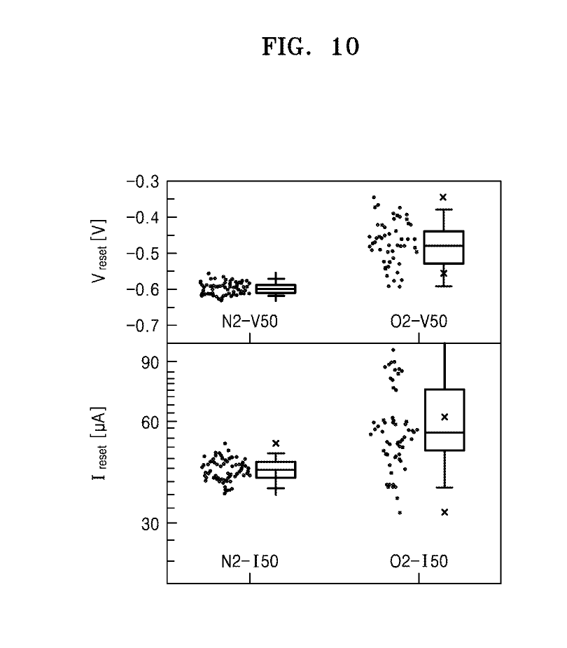

FIG. 10 is graphs illustrating distributions of a reset voltage and a reset current of a resistive memory device according to example embodiments. FIG. 10 illustrates distributions of reset voltages and reset currents in the 50th cycles of the resistive memory devices of Experimental Example 3 and Comparative Example.

Referring to FIG. 10, a reset voltage N2-V50 of Experimental Example 3 is distributed to have a narrower dispersion than a reset voltage O2-V50 of Comparative Example, and a reset current N2-I50 of Experimental Example 3 is distributed to have a narrower dispersion than a reset current O2-I50 of Comparative Example. In other words, the reset voltage N2-V50 and the reset current N2-I50 of Experimental Example 3 have relatively smaller deviations from an average value. Therefore, when the resistive memory device according to Experimental Example 3 repeatedly performs programming and erasing operations, the resistive memory device may uniformly operate even at a low compliance current.

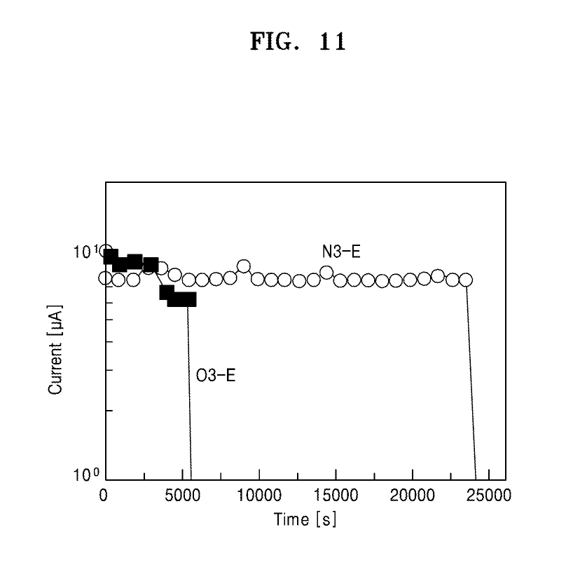

FIG. 11 is a graph illustrating a data retention characteristic of a resistive memory device according to example embodiments. Particularly, the resistive memory devices according to Experimental Example 3 and Comparative Example are programmed at a compliance current of 20 μA and then data retention characteristic thereof at 125° C. is illustrated. Referring to FIG. 11, although Experimental Example 3 N3-E may be stored at a high temperature, Experimental Example 3 N3-E may maintain a current characteristic for a significantly long period of time, compared to that of Comparative Example O3-E. In other words, a resistive memory device according to example embodiments may have a relatively higher data retention characteristic or durability at a low operation current.

A linearity and an electrical characteristic depending on a nitrogen composition of a resistive memory device according to at least some example embodiments will now be described with reference to FIGS. 12 through 14.

FIG. 12 is a graph illustrating operation characteristics of resistive memory devices including a variable resistive material layer including a variable nitrogen content.

Referring to FIG. 12, FIG. 12 illustrates voltage-current graphs of resistive memory devices according to Experimental Examples 3 through 6 N4-3.2, N4-4.8, N4-6.3, and N4-7.7 at a compliance current Ic of 100 μA.

The resistive memory device according to Experimental Example 3 N4-3.2 includes a variable resistive material layer that is formed in an atmosphere of a nitrogen gas of 3.2% and exhibits a high linearity of a voltage-current graph in a low resistance state (i.e., a low NL value). The resistive memory device according to Experimental Example 6 N4-7.7 includes a variable resistive material layer that is formed in an atmosphere of a nitrogen gas of 7.7% and exhibits a relatively lower linearity of a voltage-current graph in a low resistance state compared to that of Experimental Example 3 N4-3.2.

FIG. 13 is a graph illustrating non-linearities (NL values) of resistive memory devices including a variable resistive material layer including a variable nitrogen content. In other words, FIG. 13 illustrates a non-linearity N5-NL that is calculated from a voltage-current curve having a low resistance state by using Equation 2. X axis of FIG. 13 denotes a nitrogen gas content (%) in a process of forming a variable resistive material layer.

Referring to FIG. 13, the non-linearity may vary according to the nitrogen gas content in the process of forming the variable resistive material layer.

In detail, an NL value between about 2 and about 3.5 may correspond to an area (area I) having a nitrogen gas content between about 0% and about 3% and an area (area III) having a nitrogen gas content between about 6% and about 9%.

Also, an NL value between about 2 and about 2.5 may correspond to an area (area II) having a nitrogen gas content between about 3% and about 6%. In particular, variable resistive material layers that are formed in the area (the area II) having the nitrogen gas content between about 3% and about 6% may be tantalum oxides including nitrogen between about 2 at % and about 15 at % as described with reference to Table 1 above. In other words, resistive memory devices that use tantalum oxides including nitrogen between about 2 at % and about 15 at % as variable resistive material layers may have high linearities (i.e., a low NL value).

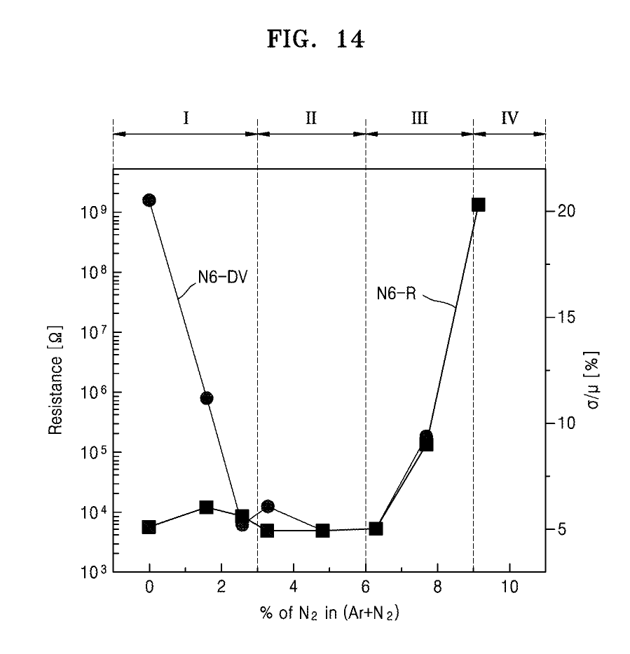

FIG. 14 is a graph illustrating resistances N6-R and deviations N6-DV of the resistances N6-R in low resistance states of resistive memory devices including a variable resistive material layer including a variable nitrogen content. X axis of FIG. 14 denotes a nitrogen gas content (%) in a process of forming a variable resistive material layer.

Referring to FIG. 14, a deviation (a ratio N6-R and a deviation to an average value) of a resistance in a low resistance state is high in an area (area I) having a nitrogen gas content between about 0% and about 3%, which may be referred to as a relatively non-uniform set operation. In particular, when a content of nitrogen is low (e.g., when a variable resistive material layer having a lower nitrogen content than 0.001 at % is formed), an effective radius of a conductive path formed in the variable resistive material layer may not sufficiently decrease. Therefore, a deviation of a resistance in a low resistance state may be relatively large. The resistance in the low resistance state is relatively high in an area (area IV) having a nitrogen gas content higher than or equal to 9%. This may be because migrations of electrons may be difficult in the variable resistive material layer in a case that a content of nitrogen is excessively high (e.g., in a case that a variable resistive material layer having a nitrogen content lower than or equal to about 30 at % is formed), thereby decreasing an electrical conductivity of the variable resistive material layer.

An area (area II) having a nitrogen gas content between about 3% and about 6% shows a sufficiently low resistance and a deviation of the sufficiently low resistance. In other words, when a variable resistive material layer having a nitrogen content between about 2 at % and about 15 at % is formed, an effective radius of a conductive path formed in the variable resistive material layer may decrease, and an operation uniformity in a low resistance state may be improved.

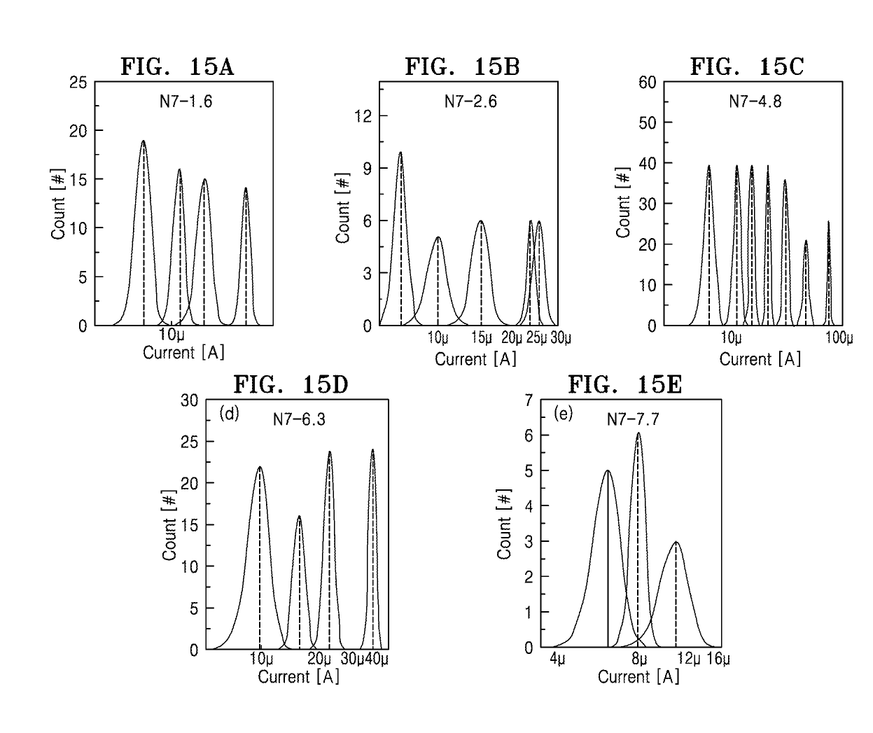

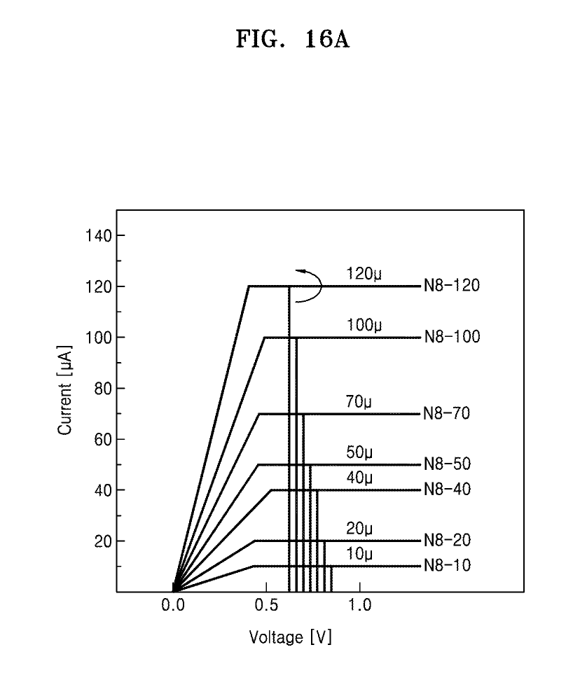

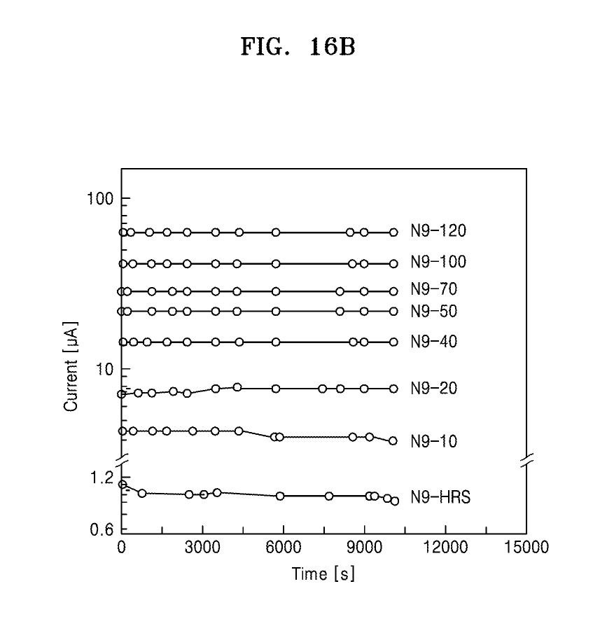

A multilevel storage characteristic will now be described with reference to FIGS. 15A through 15E, 16A, and 16B.

FIGS. 15A through 15E are graphs respectively illustrating operation current distributions for multilevel cell operations of Experimental Examples 1, 2, 4 to 6, labeled N7-1.6, N7-2.6, N7-4.8, N7-6.3, and N7-7.7, respectively.

Referring to FIGS. 15A through 15E, resistive memory devices according to example embodiments may show multilevel storage characteristics of 2 bits or more.

In particular, the operation current distribution for the multilevel cell operation of Experimental Example 4 N7-4.8 is measured at a read voltage of about 0.2V after 40 cycles of programming and erasing, and 7 discrete current distributions are shown. Therefore, the resistive memory device according to Experimental Example 4 N7-4.8 may store data of 3 bits.

FIG. 16A is a graph illustrating an operation current distribution for the multilevel cell operation of Experimental Example 3. In other words, FIG. 16A illustrates voltage-current curves depending on a compliance current Ic.

Referring to FIG. 16A, voltage-current curves N8-10, N8-20, N8-40, N8-50, N8-70, N8-100, and N8-120 at compliance currents Ic of 10 μA, 20 μA, 40 μA, 50 μA, 70 μA, 100 μA and 120 μA, respectively, have high linearities and do not overlap or interfere with one another. The resistive memory device (including a metal oxide including nitrogen of about 15 at %) according to Experimental Example 3 may store data of 3 bits.

FIG. 16B is a graph illustrating a data retention characteristic for the multilevel cell operation of Experimental Example 3. In other words, FIG. 16B illustrates current values N9-10, N9-20, N9-40, N9-50, N9-70, N9-100, and N9-120 of resistive memory devices that are stored at a temperature of 85° C. after being programmed at compliance currents Ic of 10 μA, 20 μA, 40 μA, 50 μA, 70 μA, 100 μA and 120 μA, respectively. Also, a resistive memory device N9-HRS that is not programmed and is in a high resistance state is compared together. Referring to FIG. 16B, according to Experimental Example 3, although the voltage-current curves are maintained at respective compliance currents Ic, the voltage-current curves do not overlap or interfere with one another. Therefore, the resistive memory device (including a metal oxide including nitrogen of about 15 at %) according to Experimental Example 3 has a high reliability.

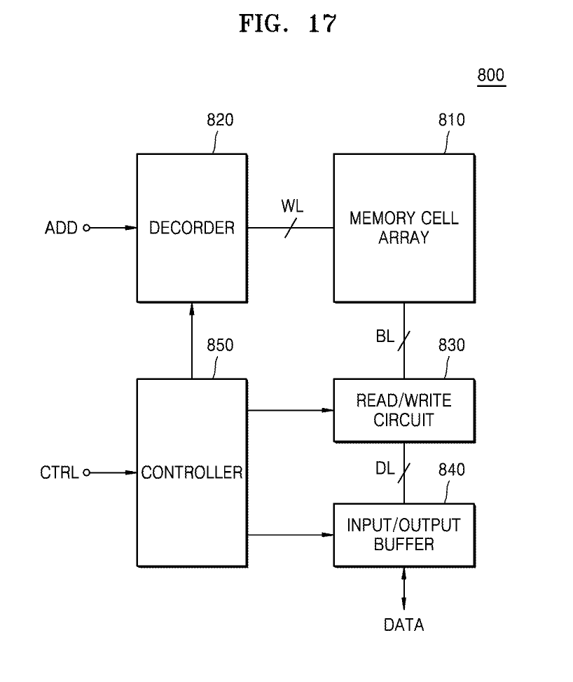

FIG. 17 is a block diagram illustrating a memory device 800 using a resistive memory device according to some example embodiments.

In detail, the memory device 800 includes a memory cell array 810, a decoder 820, a read/write circuit 830, an input/output (I/O) buffer 840, and a controller 850. The memory cell array 810 may include at least one selected from the resistive memory devices 100, 100a, 100b , 100c , and 200 described with reference to FIGS. 1 and 5 through 8.

A plurality of memory cells of the memory cell array 810 are connected to the decoder 820 through a word line WL and to the read/write circuit 830 through a bit line BL. Therefore, the decoder 820 may receive an external address ADD, and decode a row address and a column address of the memory cell array 810 that are to be accessed, under control of the controller 850 that operates according to a control signal CTRL.

The read/write circuit 830 may receive data DATA from the I/O buffer 840 and a data line DL to write data into a selected memory cell of the memory cell array 810 or read data from the selected memory cell of the memory cell array 810 under control of the controller 850 so as to provide the written or read data to the I/O buffer 840.

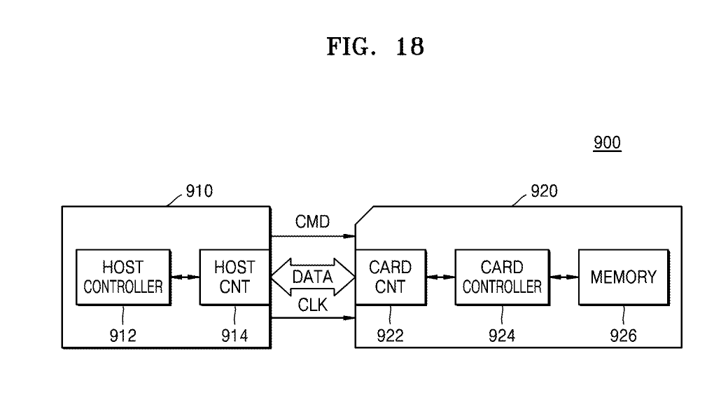

FIG. 18 is a block diagram illustrating a memory card system 900 using a resistive memory device according to some example embodiments.

Referring to FIG. 18, the memory card system 900 may include a host 910 and a memory card 920. The host 910 may include a host controller 912 and a host connector 914. The memory card 920 may include a card connector 922, a card controller 924, and a memory device 926. The memory device 926 includes at least one selected from the resistive memory devices 100, 100a, 100b , 100c , and 200 described with reference to FIGS. 1 and 5 through 8.

The host 910 may write data into the memory card 920 or read data from the memory card 920. The host controller 912 may transmit a command CMD, a clock signal generated by a clock generator (not shown) of the host 910, and data DATA to the memory card 920 through the host connector 922.

The card controller 924 may synchronize with a clock signal generated by a clock generator (not shown) of the card controller 924 to store data in the memory device 926 in response to the command CMD received through the card connector 922. The memory device 926 may store data transmitted from the host 910.

The memory card 920 may be realized as a compact flash card (CFC), a microdrive, a smart media card (SMC), a multimedia card (MMC), a security digital card (SDC), a memory stick, a universal serial bus (USB) flash memory driver, or the like.

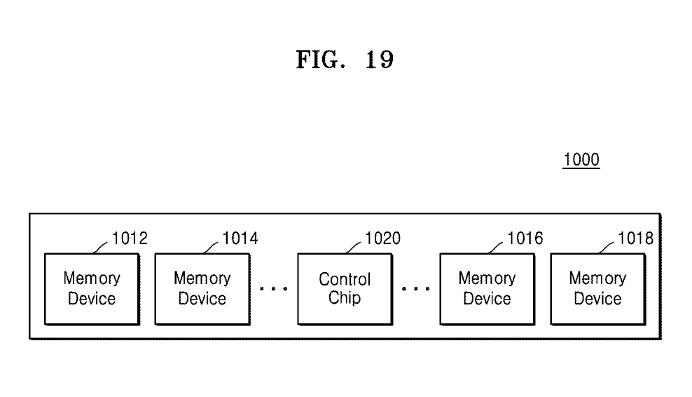

FIG. 19 is a block diagram illustrating a resistive memory module 1000 using a resistive memory device according to some example embodiments.

Referring to FIG. 19, the resistive memory module 1000 may include a plurality of memory devices 1012, 1014, 1016, and 1018 and a control chip 1020. Each of the plurality of memory devices 1012, 1014, 1016, and 1018 includes at least one selected from the resistive memory devices 100, 100a, 100b , 100c , and 200 described with reference to FIGS. 1 and 5 through 8.

The control chip 1020 may control the plurality of memory devices 1012, 1014, 1016, and 1018 in response to various types of signals transmitted from an external memory controller. For example, the control chip 1020 may activate the plurality of memory devices 1012, 1014, 1016, and 1018 corresponding to various types of commands and addresses transmitted from an external source to control write and read operations in response to the various types of commands and addresses. The control chip 1020 may also perform various types of post-processing with respect to pieces of read data respectively output from the plurality of memory devices 1012, 1014, 1016, and 1018, e.g., may perform error detection and correction operations with respect to the read data.

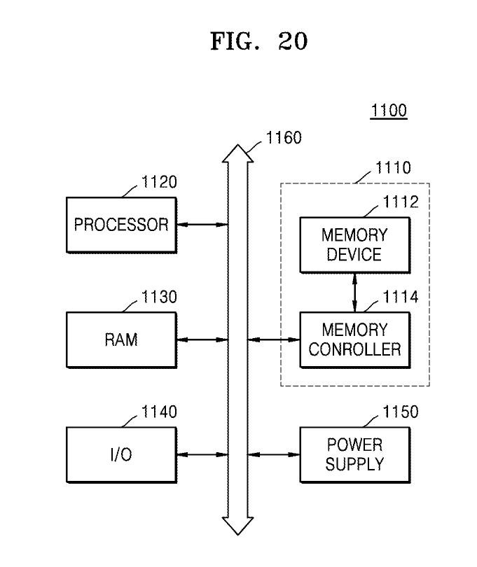

FIG. 20 is a block diagram illustrating a computing system 1100 using a resistive memory device according to some example embodiments.

Referring to FIG. 20, the computing system 1000 may include a memory system 1110, a processor 1120, a random access memory (RAM) 130, an I/O device 1140, and a power supply device 1150. The memory system 1110 may include a memory device 1112 and a memory controller 1114. Although not shown in FIG. 20, the computing system 1100 may further include ports that may communicate with a video card, a sound card, a memory card, a USB device, or other types of electronic devices. The computing system 1100 may be realized as a personal computer or a portable electronic device such as a notebook computer, a portable phone, a personal digital assistant (PDA), a camera, or the like.

The processor 1120 may perform particular calculations or tasks. According to some example embodiments, the processor 1120 may be a microprocessor or a central processing unit (CPU). The processor 1120 may communicate with the RAM 1130, the I/O device 1140, and the memory system 1110 through a bus 1160 such as an address bus, a control bus, a data bus, or the like. Here, the memory system 1110 and/or the RAM 1130 include at least one selected from the resistive memory devices 100, 100a, 100b , 100c , and 200 described with reference to FIGS. 1 and 5 through 8.

According to some example embodiments, the processor 1120 may be connected to an expansion bus such as a peripheral component interconnect (PCI) bus.

The RAM 1130 may store data necessary for an operation of the computing system 1100. The RAM 1130 may include a resistive variable memory device, a dynamic RAM (DRAM), a mobile DRAM, a static RAM (SRAM), a phase-change RAM (PRAM), a ferroelectric RAM (FRAM), or a magnetic RAM (MRAM) according to some example embodiments of the inventive concepts.

The I/O device 1140 may include input units, such as a keyboard, a keypad, a mouse, etc., and output units, such as a printer, display, etc. The power supply device 1150 may supply an operation voltage necessary for an operation of the computing system 1100.

While example embodiments of the inventive concepts have been particularly shown and described with reference to some example embodiments thereof, it will be understood that various changes in form and details may be made therein without departing from the spirit and scope of the following claims.

What is claimed is:

1. A resistive memory device comprising:
a first electrode;
a variable resistive material layer formed on the first electrode, the variable resistive material layer including a metal oxide doped with nitrogen NₓMO_{y} (wherein 0.001<x<0.30 and 0.5<y<2.5), the variable resistive material layer configured to exhibit a multibit memory characteristic; and
a second electrode formed on the variable resistive material layer.

2. The resistive memory device of claim 1, wherein the metal oxide doped with nitrogen includes one or more of a tantalum oxide doped with nitrogen, a tungsten oxide doped with nitrogen, a manganese oxide doped with nitrogen, a cobalt oxide doped with nitrogen, a titanium oxide doped with nitrogen, a hafnium oxide doped with nitrogen, and an iron oxide doped with nitrogen.

3. The resistive memory device of claim 1, wherein
the metal oxide doped with nitrogen includes a tantalum oxide NₓTaO_{y} , and 0.02<x<0.15.

4. The resistive memory device of claim 1, wherein the variable resistive material layer exhibits a bipolar memory characteristic.

5. The resistive memory device of claim 4, wherein
a current flowing through the variable resistive material layer is a set current when a set voltage is applied thereto,
a current flowing through the variable resistive material is a half set current when half of the set voltage is applied thereto, and
a ratio of the set current to the half set current is between 2 and 3.5 when the resistive memory device is operating in a low resistance state such that the resistive memory device exhibits non-linearity in the low resistance state.

6. The resistive memory device of claim 5, wherein the non-linearity exhibited by the variable resistive material layer is between 2 and 2.5.

7. The resistive memory device of claim 1, further comprising:
a conduction assisting layer between the variable resistive material layer and one or more of the first electrode and the second electrode.

8. The resistive memory device of claim 7, wherein the conduction assisting layer includes one or more of tantalum, hafnium, zirconium, aluminum, titanium, and nickel.

9. The resistive memory device of claim 7, wherein the conduction assisting layer is configured to one of supply oxygen to the variable resistive material layer or remove oxygen vacancies therefrom.

10. A resistive memory device comprising:
a plurality of first electrodes in parallel with one another;
a plurality of second electrodes crossing the plurality of first electrodes, the plurality of second electrodes in parallel with one another; and
a plurality of memory cells at cross points between the plurality of first electrodes and the plurality of second electrodes, each of the plurality of memory cells respectively including a variable resistive material layer that exhibits a multibit memory characteristic.

11. The resistive memory device of claim 10, wherein the variable resistive material layer includes a metal oxide doped with nitrogen NₓMO_{y} (wherein 0.001<x<0.30 and 0.5<y<2.5).

12. The resistive memory device of claim 11, wherein the metal oxide doped with nitrogen includes a tantalum oxide doped with nitrogen NₓTaO_{y} (wherein 0.02<x<0.15).

13. The resistive memory device of claim 10, wherein the plurality of memory cells further comprise:
a plurality of switching elements between the variable resistive material layers and the plurality of second electrodes.

14. The resistive memory device of claim 10, wherein the plurality of memory cells further comprises:
conduction assisting layers between the variable resistive material layers and the plurality of first electrodes.

15. The resistive memory device of claim 10, wherein
a current flowing through the variable resistive material layer is a set current when a set voltage is applied thereto,
a current flowing through the variable resistive material is a half set current when half of the set voltage is applied thereto, and
a ratio of the set current to the half set current is between 2 and 3.5 when operating the resistive memory device is in a low resistance state such that the resistive memory device exhibits non-linearity in the low resistance state.

16. A resistive memory device comprising:
a substrate having a first electrode thereon;
a variable resistive material layer on the first electrode, the variable resistive material layer including a metal oxide doped with nitrogen; and
a second electrode on the variable resistive material layer.

17. The resistive memory device of claim 16, wherein an atomic percentage of nitrogen in the metal oxide doped with nitrogen is between 0.1 atomic percent and 30 atomic percent.

18. The resistive memory device of claim 17, wherein
the metal oxide doped with nitrogen includes tantalum oxide, and
the atomic percentage of the nitrogen in the tantalum oxide is between 0.2 atomic percent and 15 atomic percent.

19. The resistive memory device of claim 16, wherein
a current flowing through the variable resistive material layer is a set current when a set voltage is applied thereto,
a current flowing through the variable resistive material is a half set current when half of the set voltage is applied thereto, and
a ratio of the set current to the half set current is between 2 and 3.5 when the resistive memory device is operating in a low resistance state.

20. The resistive memory device of claim 16, wherein
the resistive memory device exhibits a plurality of discrete resistance states when respective compliance currents are applied thereto are such that the resistive memory device is configured to store 3 bits of information, and
the compliance currents are between 10 μA and 120 μA.
